(19) United States
(12) Patent Application Publication
(10) Pub. No.: US 2022/0310967 A1
(43) Pub. Date: Sep. 29, 2022

(54) DISPLAY PANEL AND MANUFACTURING METHOD THEREOF

(71) Applicant: SHENZHEN CHINA STAR OPTOELECTRONICS SEMICONDUCTOR DISPLAY TECHNOLOGY CO., LTD., Shenzhen (CN)

(72) Inventor: Weijing ZENG, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/757,419

(22) PCT Filed: Apr. 3, 2020
(86) PCT No.: PCT/CN2020/083366

§ 371 Date: Apr. 20, 2020

(30) Foreign Application Priority Data
Mar. 18, 2020 (CN) 202010190012.0

(51) Int. Cl. H01L 51/52; H01L 51/56; H01L 27/32

(52) U.S. Cl. CPC H01L 51/5253; H01L 51/56; H01L 27/3246; H01L 2251/558

(57) ABSTRACT

The present disclosure provides a display panel and a manufacturing method thereof. The display panel includes an array substrate, an anode layer, a pixel definition layer, a light-emitting layer, a cathode layer, and a filling layer. The anode layer is disposed on the array substrate, the pixel definition layer covers the array substrate and the anode layer and includes a first through-hole, the light-emitting layer is disposed in the first through-hole, the cathode layer covers the pixel definition layer and the light-emitting layer and comprises a groove, and the filling layer is disposed in the groove.

### FIELD OF INVENTION

The present disclosure relates to the field of display technologies, and more particularly, to a display panel and a manufacturing method thereof.

### BACKGROUND OF INVENTION

Organic light-emitting diodes (OLEDs) have characteristics of self-illumination, high brightness, wide viewing angles, high contrast, flexibility, and low energy consumption, so they are widely applied to mobile phone screens, computer monitors, and full-color TVs. Encapsulation of OLED display panels usually adopts surface encapsulation method. However, after a thin film transistor substrate forms a film of electroluminescent layer, it will form depressions in pixel opening areas, and the areas easily generate bubbles after adopting the surface encapsulation method for encapsulation, which affects display effect and encapsulation effect of the display panels.

Technical problem: the present disclosure provides a display panel and a manufacturing method thereof to make the display panels not generate bubbles during encapsulation or subsequent processes, thereby having no influences on display effect and encapsulation effect of the display panel.

### SUMMARY OF INVENTION

An embodiment of the present disclosure provides a display panel which comprises:

an array substrate;

an anode layer disposed on the array substrate;

a pixel definition layer covering the array substrate and the anode layer, wherein the pixel definition layer comprises a first through-hole penetrating through the pixel definition layer to expose the anode layer;

a light-emitting layer disposed in the first through-hole to electrically connect to the anode layer;

a cathode layer covering the pixel definition layer and the light-emitting layer, wherein the cathode layer comprises a groove defined on the first through-hole; and

a filling layer disposed in the groove and on the cathode layer.

In the display panel according to an embodiment of the present disclosure, a sum of thicknesses of the anode layer, the light-emitting layer, the cathode layer, and the filling layer is greater than a thickness of the pixel definition layer.

In the display panel according to an embodiment of the present disclosure, a material of the filling layer comprises one or more of polyimide, polyethylene, polyethylene naphthalate, or hexamethyldimethylsilyl ether.

In the display panel according to an embodiment of the present disclosure, a surface of the filling layer is higher than a surface of the cathode layer or is flush with the surface of the cathode layer.

The display panel according to an embodiment of the present disclosure, further comprises a blocking layer covering the cathode layer and the filling layer.

The display panel according to an embodiment of the present disclosure, further comprises a planarization layer disposed on the array substrate, wherein the planarization layer comprises a second through-hole penetrating through the planarization layer to expose the array substrate, and the anode layer is disposed in the second through-hole and on the planarization layer to electrically connect to the array substrate.

The display panel according to an embodiment of the present disclosure, further comprises an encapsulation layer disposed on the blocking layer.

The display panel according to an embodiment of the present disclosure, further comprises a capping layer disposed on the encapsulation layer.

An embodiment of the present disclosure further provides a display panel which comprises:

an array substrate;

an anode layer disposed on the array substrate;

a pixel definition layer covering the array substrate and the anode layer, wherein the pixel definition layer comprises a first through-hole penetrating through the pixel definition layer to expose the anode layer;

a light-emitting layer disposed in the first through-hole to electrically connect to the anode layer;

a cathode layer covering the pixel definition layer and the light-emitting layer, wherein the cathode layer comprises a groove defined on the first through-hole; and

a filling layer disposed in the groove.

In the display panel according to an embodiment of the present disclosure, a sum of thicknesses of the anode layer, the light-emitting layer, the cathode layer, and the filling layer is greater than a thickness of the pixel definition layer.

In the display panel according to an embodiment of the present disclosure, a material of the filling layer comprises one or more of polyimide, polyethylene, polyethylene naphthalate, or hexamethyldimethylsilyl ether.

In the display panel according to an embodiment of the present disclosure, a surface of the filling layer is higher than a surface of the cathode layer or is flush with the surface of the cathode layer.

The display panel according to an embodiment of the present disclosure, further comprises a blocking layer covering the cathode layer and the filling layer.

The display panel according to an embodiment of the present disclosure, further comprises a planarization layer disposed on the array substrate, wherein the planarization layer comprises a second through-hole penetrating through the planarization layer to expose the array substrate, and the anode layer is disposed in the second through-hole and on the planarization layer to electrically connect to the array substrate.

The display panel according to an embodiment of the present disclosure, further comprising an encapsulation layer disposed on the blocking layer.

The display panel according to an embodiment of the present disclosure, further comprises a capping layer disposed on the encapsulation layer.

An embodiment of the present disclosure further provides a manufacturing method of a display panel. The method comprises following steps:

providing an array substrate;

disposing an anode layer on the array substrate;

disposing a pixel definition layer on the anode layer;

etching the pixel definition layer to form a first through-hole penetrating through the pixel definition layer to expose the anode layer;

disposing a light-emitting layer in the first through-hole;

covering a cathode layer on the pixel definition layer and the light-emitting layer, wherein the cathode layer comprises a groove defined on the first through-hole; and

printing a material of a filling layer in the groove by inkjet printing to form the filling layer.

In the manufacturing method of the display panel according to an embodiment of the present disclosure, after the step of printing the material of the filling layer in the groove by inkjet printing to form the filling layer, the method further comprises disposing a blocking layer on the cathode layer and the filling layer.

In the manufacturing method of the display panel according to an embodiment of the present disclosure, after the step of disposing the blocking layer on the cathode layer and the filling layer, the method further comprises disposing an encapsulation layer on the blocking layer.

In the manufacturing method of the display panel according to an embodiment of the present disclosure, a surface of the filling layer is higher than a surface of the cathode layer or is flush with the surface of the cathode layer.

Beneficial effect: the present disclosure provides a display panel and a manufacturing method thereof. The display panel comprises an array substrate, an anode layer, a pixel definition layer, a light-emitting layer, a cathode layer, and a filling layer. The anode layer is disposed on the array substrate, and the pixel definition layer covers the array substrate and the anode layer and comprises a first through-hole penetrating through the pixel definition layer to expose the anode layer. The light-emitting layer is disposed in the first through-hole to electrically connect to the anode layer, the cathode layer covers the pixel definition layer and the light-emitting layer and comprises a groove defined on the first through-hole, and the filling layer is disposed in the groove. In the present disclosure, the filling layer is disposed in the groove of the cathode layer to prevent the display panel from generating bubbles during subsequent encapsulation process, thereby improving encapsulation effect and display effect of the display panel.

### DESCRIPTION OF DRAWINGS

The accompanying figures to be used in the description of embodiments of the present disclosure will be described in brief to more clearly illustrate the technical solutions of the embodiments. The accompanying figures described below are only part of the embodiments of the present disclosure, from which those skilled in the art can derive further figures without making any inventive efforts.

FIG. 1 is a first schematic structural diagram of a display panel according to an embodiment of the present disclosure.

FIG. 2 is a schematic structural diagram of an array substrate according to an embodiment of the present disclosure.

FIG. 3 is a second schematic structural diagram of a display panel according to an embodiment of the present disclosure.

FIG. 4 is a flowchart of a manufacturing method of a display panel according to an embodiment of the present disclosure.

### DETAILED DESCRIPTION OF PREFERRED EMBODIMENTS

The embodiments of the present disclosure are described in detail hereinafter. Examples of the described embodiments are given in the accompanying drawings. The specific embodiments described with reference to the attached drawings are all exemplary and are intended to illustrate and interpret the present disclosure. Based on the embodiments in the present disclosure, all other embodiments obtained by those skilled in the art without creative efforts are within the scope of the present disclosure.

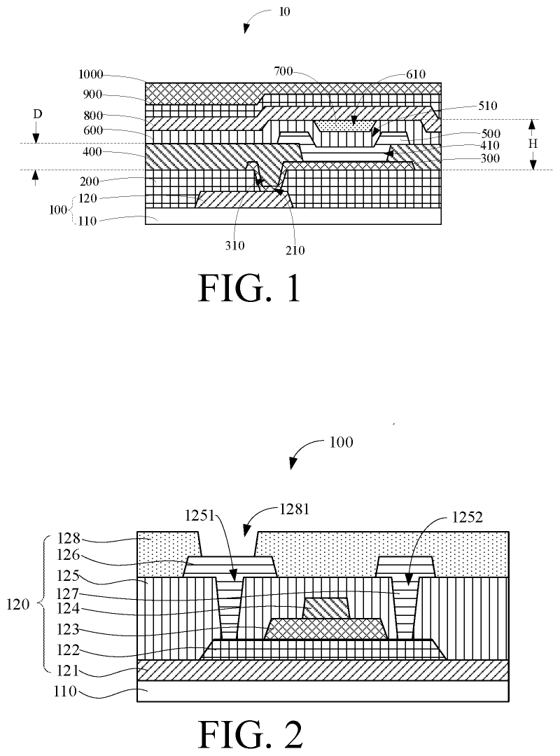

Referring to FIG. 1, FIG. 1 is a first schematic structural diagram of a display panel according to an embodiment of the present disclosure. An embodiment of the present disclosure provides a display panel 10. The display panel 10 comprises an array substrate 100, an anode layer 300, a pixel definition layer 400, a light-emitting layer 500, a cathode layer 600, and a filling layer 700.

Referring to FIG. 2, FIG. 2 is a schematic structural diagram of an array substrate according to an embodiment of the present disclosure. The array substrate 100 comprises a substrate 110 and a thin film transistor 120. The thin film transistor 120 is disposed on the substrate 110. The thin film transistor 120 includes a buffer layer 121, an active layer 122, a gate insulating layer 123, a gate electrode layer 124, an interlayer dielectric layer 125, a source electrode 126, and a drain electrode 127. The buffer layer 121 is disposed on the substrate 110. A material of the buffer layer 121 comprises SiOₓ and SiNₓ. The active layer 122 is disposed on the buffer layer 121. A material of the active layer 122 comprises indium gallium zinc oxide, indium zinc tin oxide, gallium zinc oxide, zinc oxynitride, and indium gallium zinc titanium oxide. The gate insulating layer 123 is disposed on the active layer 122. A material of the gate insulating layer 123 comprises SiOₓ and SiNₓ. The gate electrode layer 124 is disposed on the gate insulating layer 123. A material of the gate electrode layer 124 comprises one or more of Mo, Al, Cu, or Ti. The interlayer dielectric layer 125 covers the buffer layer 121, the active layer 122, the gate insulating layer 123, and the gate electrode layer 124. The interlayer dielectric layer 125 has a third through-hole 1251 and a fourth through-hole 1252. The third through-hole 1251 penetrates through the interlayer dielectric layer 125 to expose one side of the active layer 122. The fourth through-hole 1252 penetrates through the interlayer dielectric layer 125 to expose another side of the active layer 122. A material of the interlayer dielectric layer 125 comprises SiOₓ and SiNₓ. The source electrode 126 is filled in the third through-hole 1251 and disposed on the interlayer dielectric layer 125 to electrically connect to the active layer 122. The drain electrode 127 is filled in the fourth through-hole 1252 and disposed on the interlayer dielectric layer 125 to electrically connect to the active layer 122. Materials of the source electrode 126 and the drain electrode 127 comprise one or more of Mo, Al, Cu, or Ti.

The display panel 10 further comprises a planarization layer 200. The planarization layer 200 is disposed on the substrate 110 and the thin film transistor 120. The planarization layer 200 includes a second through-hole 210. The second through-hole 210 penetrates through the planarization layer 200 to expose the thin film transistor 120. A material of the planarization layer 200 comprises SiOₓ and SiNₓ.

The anode layer 300 is disposed in the second through-hole 210 and on the planarization layer 200 and is electrically connected to the thin film transistor 120. The anode layer 300 has a first filling groove 310.

The pixel definition layer 400 covers the planarization layer 200 and the anode layer 300. The pixel definition layer 400 includes a first through-hole 410. The first through-hole 410 penetrates through the pixel definition layer 400 to expose the anode layer 300.

The light-emitting layer 500 is disposed in the first through-hole 410 to electrically connect to the anode layer 300. The light-emitting layer 500 has a second filling groove 510.

In another embodiment, an electron transport layer and a hole transport layer are further disposed in the first through-hole 410.

The cathode layer 600 covers the pixel definition layer 400 and the light-emitting layer 500. The cathode layer 600 includes a groove 610. The groove 610 is positioned on the first through-hole 410.

The filling layer 700 is disposed in the groove 610. A surface of the filling layer 700 is flush with a surface of the cathode layer 600. A material of the filling layer 700 comprises one or more of polyimide, polyethylene, polyethylene naphthalate, or hexamethyldimethylsilyl ether. A sum H of thicknesses of the anode layer 300, the light-emitting layer 500, the cathode layer 600, and the filling layer 700 on the first through-hole 410 is greater than a thickness D of the pixel definition layer 400.

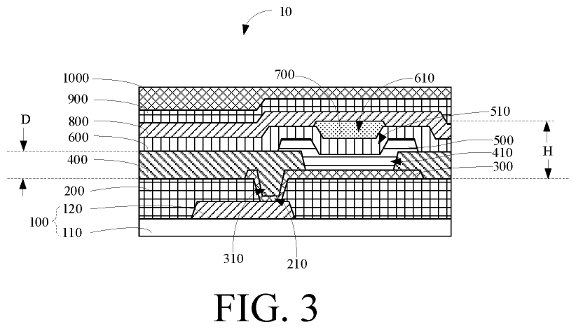

Referring to FIG. 3, FIG. 3 is a second schematic structural diagram of a display panel according to an embodiment of the present disclosure. The filling layer 700 is disposed in the groove 610 and on the cathode layer 600. The surface of the filling layer 700 is higher than the surface of the cathode layer 600.

In another embodiment of the present disclosure, the display panel 10 further includes a blocking layer 800. The blocking layer 800 covers the cathode layer 600 and the filling layer 700.

In another embodiment of the present disclosure, the display panel 10 further comprises an encapsulation layer 900. The encapsulation layer 900 covers the blocking layer 800.

In another embodiment of the present disclosure, the display panel 10 further includes a capping layer 1000. The capping layer 1000 is disposed on the encapsulation layer 900.

In the present disclosure, the filling layer 700 is disposed in the groove 610 of the cathode layer 600 to prevent the display panel 10 from generating bubbles during subsequent encapsulation process, thereby improving encapsulation effect and display effect of the display panel.

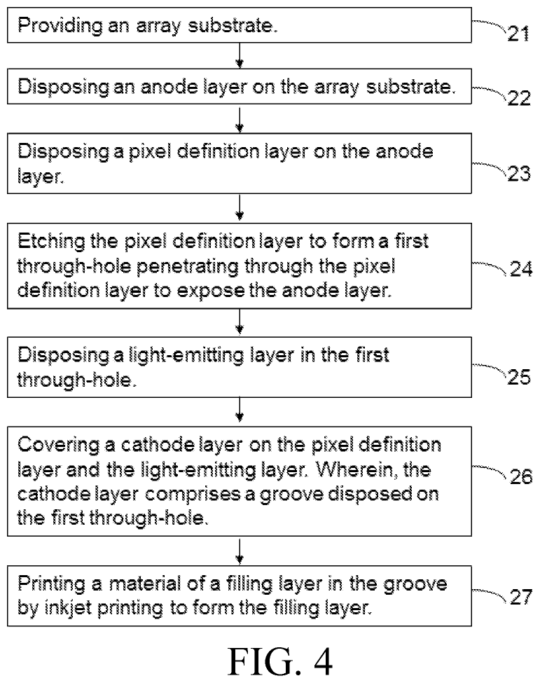

Referring to FIG. 4, FIG. 4 is a flowchart of a manufacturing method of a display panel according to an embodiment of the present disclosure. An embodiment of the present disclosure further provides a manufacturing method of a display panel. The manufacturing method comprises following steps:

step 21: providing an array substrate 100.

The array substrate 100 comprises a substrate 110 and a thin film transistor 120. The thin film transistor 120 is disposed on the substrate 110. A chemical vapor deposition process or a physical vapor deposition process is used to deposit a material of a buffer layer on the substrate 110 to form the buffer layer 121. The material of the buffer layer 121 comprises SiOₓ and SiNₓ. A chemical vapor deposition process is used to deposit a material of an active layer 122 on the buffer layer 121, and the material of the active layer 122 is etched to form the active layer 122. The material of the active layer 122 comprises indium gallium zinc oxide, indium zinc tin oxide, gallium zinc oxide, zinc oxynitride, and indium gallium zinc titanium oxide. A chemical vapor deposition process or a physical vapor deposition process is used to deposit a material of a gate insulating layer on the active layer 122, and the material of the gate insulating layer is etched to form the gate insulating layer 123. The material of the gate insulating layer 123 comprises SiOₓ and SiNₓ. A physical vapor deposition process is used to deposit a material of a gate electrode layer on the gate insulating layer 123, and the material of the gate electrode layer is etched to form the gate electrode layer 124. The material of the gate electrode layer 124 comprises one or more of Mo, Al, Cu, or Ti. The active layer 122 is partially conductorized, thereby having characteristics of conductor and semiconductor. An interlayer dielectric layer 125 is covered on the buffer layer 121, the active layer 122, the gate insulating layer 123, and the gate electrode layer 124. The interlayer dielectric layer 125 is etched to form a third through-hole 1251 and a fourth through-hole 1252. The third through-hole 1251 penetrates through the interlayer dielectric layer 125 to expose one side of the active layer 122. The fourth through-hole 1252 penetrates through the interlayer dielectric layer 125 to expose another side of the active layer 122. A material of a source electrode is deposited on the interlayer dielectric layer 125 and in the third through-hole 1251 and is etched to form the source electrode 126. The material of the source electrode 126 comprises one or more of Mo, Al, Cu, or Ti. A material of a drain electrode is deposited on the interlayer dielectric layer 125 and in the fourth through-hole 1252 and is etched to form the drain electrode 127. The material of the drain electrode 127 comprises one or more of Mo, Al, Cu, or Ti.

In another embodiment of the present disclosure, after the process of the array substrate 100 is completed, the method further comprises depositing a material of a planarization layer 200 on the array substrate 100 to form the planarization layer 200. The planarization layer 200 is etched to form a second through-hole 210. The second through-hole 210 penetrates through the planarization layer 200 to expose the thin film transistor 120. The material of the planarization layer 200 comprises SiOₓ and SiNₓ.

Step 22: disposing an anode layer 300 on the array substrate 100.

A chemical vapor deposition process is used to form the anode layer 300 on the planarization layer 200 and in the second through-hole 210. The anode layer 300 is etched to form a first filling groove 310. A material of the anode layer comprises indium tin oxide.

Step 23: disposing a pixel definition layer 400 on the anode layer 300.

The pixel definition layer 400 is formed on the planarization layer 200 and the anode layer 300.

Step 24: etching the pixel definition layer 400 to form a first through-hole 410 penetrating through the pixel definition layer 400 to expose the anode layer 300.

Step 25: disposing a light-emitting layer 500 in the first through-hole 410.

Evaporation or inkjet printing is used to form a light-emitting layer 500 in the first through-hole 410 and on the pixel definition layer 400. The light-emitting layer has a second filling groove 510. The second filling groove 510 is positioned on the first through-hole 410.

In another embodiment of the present disclosure, an electron transport layer and a hole transport layer are further formed in the first through-hole 410 and on the pixel definition layer 400.

Step 26: covering a cathode layer 600 on the pixel definition layer 400 and the light-emitting layer 500. Wherein, the cathode layer 600 comprises a groove 610 defined on the first through-hole 410.

Evaporation or inkjet printing is used to form the cathode layer 600 on the pixel definition layer 400 and the light-emitting layer 500. The cathode layer 600 is provided with a groove 610.

Step 27: printing a material of a filling layer in the groove 610 by inkjet printing to form the filling layer 700.

A surface of the filling layer 700 is flush with a surface of the cathode layer 600 or higher than the surface of the cathode layer 600. The material of the filling layer 700 comprises one or more of polyimide, polyethylene, polyethylene naphthalate, or hexamethyldimethylsilyl ether. A sum H of thicknesses of the anode layer 300, the light-emitting layer 500, the cathode layer 600, and the filling layer 700 on the first through-hole 410 is greater than a thickness D of the pixel definition layer 400.

In another embodiment of the present disclosure, after the step of disposing the filling layer 700 in the groove 610, the method further comprises forming a blocking layer 800 covering the cathode layer 600 and the filling layer 700.

In another embodiment of the present disclosure, after the step of forming the blocking layer 800 on the cathode layer 600 and the filling layer 700, the method further comprises forming an encapsulation layer 900 on the blocking layer 800.

In another embodiment of the present disclosure, after the step of forming the encapsulation layer 900 on the blocking layer 800, the method further comprises forming a capping layer 100 on the encapsulation layer 900.

The present disclosure provides a display panel and a manufacturing method thereof. The display panel comprises an array substrate, an anode layer, a pixel definition layer, a light-emitting layer, a cathode layer, and a filling layer. The anode layer is disposed on the array substrate, and the pixel definition layer covers the array substrate and the anode layer and comprises a first through-hole penetrating through the pixel definition layer to expose the anode layer. The light-emitting layer is disposed in the first through-hole to electrically connect to the anode layer, the cathode layer covers the pixel definition layer and the light-emitting layer and comprises a groove defined on the first through-hole, and the filling layer is disposed in the groove. In the present disclosure, the filling layer is disposed in the groove of the cathode layer to prevent the display panel from generating bubbles during subsequent encapsulation process, thereby improving encapsulation effect and display effect of the display panel.

The present disclosure has been described with a preferred embodiment thereof. The preferred embodiment is not intended to limit the present disclosure, and it is understood that many changes and modifications to the described embodiment can be carried out without departing from the scope and the spirit of the disclosure.

1. A display panel, comprising:
an array substrate;
an anode layer disposed on the array substrate;
a pixel definition layer covering the array substrate and the anode layer, wherein the pixel definition layer comprises a first through-hole penetrating through the pixel definition layer to expose the anode layer;
a light-emitting layer disposed in the first through-hole to electrically connect to the anode layer;
a cathode layer covering the pixel definition layer and the light-emitting layer, wherein the cathode layer comprises a groove defined on the first through-hole; and
a filling layer disposed in the groove and on the cathode layer.

2. The display panel according to claim 1, wherein a sum of thicknesses of the anode layer, the light-emitting layer, the cathode layer, and the filling layer is greater than a thickness of the pixel definition layer.

3. The display panel according to claim 1, wherein a material of the filling layer comprises one or more of polyimide, polyethylene, polyethylene naphthalate, or hexamethyldimethylsilyl ether.

4. The display panel according to claim 1, wherein a surface of the filling layer is higher than a surface of the cathode layer or is flush with the surface of the cathode layer.

5. The display panel according to claim 1, further comprising a blocking layer covering the cathode layer and the filling layer.

6. The display panel according to claim 1, further comprising a planarization layer disposed on the array substrate, wherein the planarization layer comprises a second through-hole penetrating through the planarization layer to expose the array substrate, and the anode layer is disposed in the second through-hole and on the planarization layer to electrically connect to the array substrate.

7. The display panel according to claim 5, further comprising an encapsulation layer disposed on the blocking layer.

8. The display panel according to claim 7, further comprising a capping layer disposed on the encapsulation layer.

9. A display panel, comprising:
an array substrate;
an anode layer disposed on the array substrate;
a pixel definition layer covering the array substrate and the anode layer, wherein the pixel definition layer comprises a first through-hole penetrating through the pixel definition layer to expose the anode layer;
a light-emitting layer disposed in the first through-hole to electrically connect to the anode layer;
a cathode layer covering the pixel definition layer and the light-emitting layer, wherein the cathode layer comprises a groove defined on the first through-hole; and
a filling layer disposed in the groove.

10. The display panel according to claim 9, wherein a sum of thicknesses of the anode layer, the light-emitting layer, the cathode layer, and the filling layer is greater than a thickness of the pixel definition layer.

11. The display panel according to claim 9, wherein a material of the filling layer comprises one or more of polyimide, polyethylene, polyethylene naphthalate, or hexamethyldimethylsilyl ether.

12. The display panel according to claim 9, wherein a surface of the filling layer is higher than a surface of the cathode layer or is flush with the surface of the cathode layer.

13. The display panel according to claim 9, further comprising a blocking layer covering the cathode layer and the filling layer.

14. The display panel according to claim 9, further comprising a planarization layer disposed on the array substrate, wherein the planarization layer comprises a second through-hole penetrating through the planarization layer to expose the array substrate, and the anode layer is disposed in the second through-hole and on the planarization layer to electrically connect to the array substrate.

15. The display panel according to claim 13, further comprising an encapsulation layer disposed on the blocking layer.

16. The display panel according to claim 15, further comprising a capping layer disposed on the encapsulation layer.

17. A manufacturing method of a display panel, comprising following steps:
providing an array substrate;
disposing an anode layer on the array substrate;
disposing a pixel definition layer on the anode layer;
etching the pixel definition layer to form a first through-hole penetrating through the pixel definition layer to expose the anode layer;
disposing a light-emitting layer in the first through-hole;
covering a cathode layer on the pixel definition layer and the light-emitting layer, wherein the cathode layer comprises a groove defined on the first through-hole; and
printing a material of a filling layer in the groove by inkjet printing to form the filling layer.

18. The manufacturing method of the display panel according to claim 17, wherein after the step of printing the material of the filling layer in the groove by inkjet printing to form the filling layer, the method further comprises disposing a blocking layer on the cathode layer and the filling layer.

19. The manufacturing method of the display panel according to claim 18, wherein after the step of disposing the blocking layer on the cathode layer and the filling layer, the method further comprises disposing an encapsulation layer on the blocking layer.

20. The manufacturing method of the display panel according to claim 17, wherein a surface of the filling layer is higher than a surface of the cathode layer or is flush with the surface of the cathode layer.
